(19) United States
(12) Patent Application Publication
(10) Pub. No.: US 2003/0197228 A1
(43) Pub. Date: Oct. 23, 2003

(54) CMOS image sensor and method of fabricating the same

(75) Inventors: Shoji Okuda, Kuwana (JP); Masatoshi Takami, Kuwana (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/373,793

(22) Filed: Feb. 27, 2003

(30) Foreign Application Priority Data
Mar. 7, 2002 (JP) 2002-62580

(51) Int. Cl. H01L 29/76; H01L 31/062

(52) U.S. Cl. 257/369; 438/199; 257/371; 438/223; 257/383

(57) ABSTRACT

To solve the problem that when a high temperature heat treatment is avoided, a substrate leak current increases due to the interfacial level generated with a plasma damage and thereby clearness of the CMOS image sensor is deteriorated. There is provided a CMOS image sensor characterized in using an epitaxial wafer as an element substrate, and more particularly to a CMOS image sensor characterized in that a tungsten layer is formed after formation of a contact hole used for connection between the elements in the element substrate and wirings and after the tungsten layer is removed from the area other than the contact hole, the annealing is conducted under the nitrogen and hydrogen atmosphere or under the hydrogen atmosphere.

### CROSS-REFERENCE TO RELATED APPLICATIONS

This application is based upon and claims the benefit of priority from the prior Japanese Patent Application No. 2002-62580, filed Mar. 7, 2002, the entire contents of which are incorporated herein by reference.

### BACKGROUND OF THE INVENTION

1. Field of the Invention

The present invention relates to a CMOS image sensor and a method of fabricating the same. More particularly, the present invention relates to an improved technique for preventing damage which will be generated in the course of fabrication under the condition that a CMOS image sensor formed of photodiodes and MOS transistors formed on a semiconductor substrate is integrated in the higher packing density or in the scale-down packing method.

2. Description of the Related Art

A fabrication technique of CMOS image sensor of the prior art will be explained briefly.

In recent years, the CMOS image sensor has been used widely as a solid-state imaging element. The CMOS image sensor has various merits in that power consumption is small in comparison with a CCD (Charge Coupled Device), the sensor being driven with a single power supply and the peripheral circuits (such as, timing generation circuit, read circuit and A/D converter) being formed integrally.

Refer to FIG. 21:

FIG. 21 is an equivalent circuit of a pixel of CMOS image sensor. One pixel of the CMOS image sensor illustrated in FIG. 21 is formed of a photodiode PD, three N-channel MOS transistors T1, T2, T3. The cathode of photodiode PD is connected to the drain of transistor T1 and the gate of transistor T2. The sources of transistors T1, T2 are connected to the power supply line to which the reference voltage VR is supplied. Moreover, the gate of transistor T1 is connected to the reset line to which a reset signal RST is supplied.

The source of transistor Te is connected to the drain of transistor T2. The drain is connected to the read circuit (not illustrated) via a signal line; and the gate is connected to a column selection line to which a select signal SLCT is supplied. The transistor T1 is called the reset transistor, while the transistor T2 is the drive transistor and the transistor T3 is the selection transistor.

In the CMOS image transistor, a plurality of pixels indicated by an equivalent circuit in FIG. 21 are arranged in the horizontal and vertical directions and the peripheral circuits (such as, read circuit and A/D (analog to digital) converting circuit) are formed in the external side of the area where these pixels are formed.

The Japanese Unexamined Patent Application Publication No. 1998-248035 discloses a driving method in which the potential of the signal supplied to the gate of reset transistor is changed in three steps to expand the dynamic range of the CMOS image sensor.

Various improvements have been implemented to such CMOS image sensor for further scale-down of elements, for example, RTA (rabbit thermal annealing) heat treatment for heating using a lamp to rapidly raise the temperature within a short period, wet oxidation for oxidation under the atmosphere including vapor to effectively form an oxide film within a short period of time, introduction of Ti (titanium) into a part of the wirings as a measure to prevent electro-migration which tends to be generated in the fine wiring layer and employment of a method to reduce as much as possible the heat treatment record itself during the process.

Problem:

However, according to the employment of RTA and wet oxidation, since rapid temperature rise and sudden oxidation are executed, thermal stress is stored in the substrate on which elements are formed; and thereby, a problem occurs in that a crystal defect may be generated easily due to such stored stress. Such crystal defect does not result increase of a leak current; and therefore, a leak current in the CMOS image sensor will be explained.

When the circuit illustrated in FIG. 21 is formed on a semiconductor substrate, it is necessary to electrically connect the source/drain of the MOS transistor formed on the semiconductor substrate and the wirings formed on the semiconductor substrate via an insulation film. When a contact hole is only formed on the insulation film and a conductor is only embedded to the contact hole, a contact resistor between the conductor and source/drain increases. Here, it is also thought that a resistance value can be reduced by forming a silicide film on the surface of the source/drain of the MOS transistor and then electrically connecting the source/drain and the wirings via the silicide film. However, in such a case, a leak current increases at the connecting portion of the reset transistor and photodiode resulting in the cause of the deterioration of characteristic. The leak current includes a peripheral side length element, which leaks at the edge portion of the field oxide film and an area element, which leaks at the PN junction area.

A cause of the leak at the peripheral side length element is thought to be the injected ion being absorbed with the silicide and the ion concentration becoming thinner at the part where the injected ion concentration becomes thinner at the edge of the field oxide film. Moreover, the area element is also assumed to increase owing to contamination of depletion layer with atom of metals when the silicide is formed and to the crystal defect caused by formation of silicide.

As explained above, it is the first object of the present invention to reduce a resistance value between the source/drain of MOS transistor and wirings and to control a leak current at the drain of the reset transistor. Meanwhile, an attempt to prevent electro-migration through employment of Ti to a part of the wiring obviously generates a problem that recovery effect of the interfacial level is deteriorated because hydrogen under the heat treatment atmosphere to be executed to cover the interfacial level is absorbed with Ti. In addition, a problem also occurs whereby the hot carrier is deteriorated if HDP CVD-SiO₂ film (high density CVD silicon oxide film) is employed as an insulation film deposited and formed on the flat surface of the element substrate.

### BRIEF SUMMARY OF THE INVENTION

The present invention employs the following structures as the principal means for solving the problems explained above.

(1) There is disclosed a CMOS image sensor having employed an epitaxial wafer as an element substrate on which the element isolating insulation film provided on the element substrate is provided with the LOCOS method and the bird beak is also generated. The element isolating insulation film of this CMOS image sensor is the LOCOS film formed under the dry oxidation atmosphere. An active area provided in the element substrate is formed by diffusion through the heat treatment within the furnace after the ion injection of a conductive impurity. A contact window is formed for mutual connection between the active area in the element substrate; and wirings formed on the element substrate; and a conductive impurity which enables compensation for contact is not injected to the bottom part of the contact window. A contact window used for mutual connection of the active area in the element substrate and wirings formed on the element substrate is formed; and a conductive impurity which enables compensation for contact is formed at the bottom part of the contact window through thermal diffusion after impurity ion injection. The wirings formed on the element substrate does not include Ti (titanium).

(2) Wirings consisting of Ti formed on the element substrate, a layer consisting of W (tungsten) formed within the contact window used for connections among the wirings or connection between the active area in the element substrate and wirings and a TiN (titanium nitride) layer formed to cover the upper and lower surfaces of the wirings are provided. Alternatively, a part or the entire part of the TiN layer are formed with the thermal nitride process of wirings consisting of Ti.

(3) There is disclosed a method of fabricating a CMOS image sensor comprising the steps of depositing and forming a W (tungsten)-wiring layer to a contact window provided by forming an opening to the interlayer insulation film on the element area within the element substrate; and thereafter, removing the W-wiring layer from the external side of the contact window and conducting the heat treatment under the atmosphere including nitrogen and hydrogen or under the hydrogen atmosphere to the structures of remainders of such processes.

Next, operations of the present invention will be explained.

According to the present invention, a crystal defect in the substrate due to the stress can be reduced by using an epitaxial wafer, forming a thick initial oxide film to easily generate bird beak and then conducting oxidation under the dry atmosphere when LOCOS film is formed. Moreover, the crystal defect in the substrate is reduced by doping impurity with the ion injection when the source and drain are formed; and thereafter, conducting the annealing within the furnace. During the fabrication process up to the formation of an opening of the window for wire bonding, the interfacial level generated with plasma damage is recovered with the annealing, but when Ti is used in the wiring process, Ti absorbs hydrogen; and thereby, the annealing effect to be recovered can be reduced. Therefore, the absorption effect of hydrogen can be lowered by not using Ti into the wiring structure or introducing the structure that Ti is sandwiched with TiN. In the case where Ti must be used for the wiring structure to improve electro-migration, it is enough to form a structure that a plasma oxide film is grown on an element, a plasma nitride film with a high refractive index (refractive index=2.24) having grown thereon and hydrogen in the film being directly supplied for recovery of interfacial level. Since the plasma nitride film having a higher refractive index (refractive index=2.24) includes a large amount of silicon and hydrogen, this film shows the behavior of semiconductor material; and therefore, a plasma oxide film is grown under the plasma nitride film in order to prevent leak of signal among the gate, source and drain. Here, a plasma TEOS is grown on the plasma nitride film and the surface is flattened with CMP. In this case, the plasma oxide film, plasma nitride film and plasma TEOS may also be used in the method for fabricating the device other than the CMOS image sensor and are also effective for the hot carrier. The reason why three kinds of plasma films are used here is that the film may can be formed even under a low temperature in order to avoid the thermal influence in the silicide process. The film forming temperature by the plasma ranges from 350 to 400; and a parallel flat plate type plasma CVD apparatus is therefore used to form these plasma films. In the course of the process, the annealing process may also be conducted for recovery of interfacial level, but this annealing process should be conducted after formation of the tungsten (W) plug (after tungsten is removed from the part other than the contact hole). After growth of the plasma TEOS film, the interfacial level generated when the contact hole is formed cannot be recovered. After the contact hole is formed, the suicides formed on the source and drain are thermally influenced to provide a variation of contact resistance. After formation of the wirings, a problem occurs whereby the wiring resistance becomes higher due to the heat treatment

Refer to FIG. 1:

FIG. 1 is a graph to explain a comparison of life spans of hot carriers depending on difference of interlayer structures. The horizontal axis indicates a substrate leak current (IBB), while the vertical axis indicates life spans of hot carriers for comparison between the laminated film of the silicon nitride film and high density plasma CVD oxide film (lower side line) and the laminated film of the silicon nitride film and TEOS oxide film (upper side line). The life span of hot carrier and substrate leak current of the laminated film of the silicon nitride film and high density CVD oxide film are lower for the entire range. Therefore, it can be understood that the high density plasma CVD film is more desirable as the oxide film to be combined with the silicon nitride film. A crystal defect in the substrate due to the stress can be reduced and the interfacial level generated by plasma damage can also be recovered.

Here, Ti (titanium) reduces the effect of interfacial level recovery annealing process with its nature to absorb hydrogen. However, since TiN (titanium nitride) does not absorb hydrogen, a problem in which the effect of interfacial level recovery annealing process is reduced does not occur even when Ti (titanium) is included. Therefore, the material TiN can be used without any problem. Accordingly, it is generally recommended that a metal film having the to absorb hydrogen is not used.

Moreover, the inventors of the present invention have also recognized that a crystal defect can be considerably lowered through the use of epitaxial wafer and deposition and formation of a plasma CVD-TEOS oxide film. Since a crystal defect certainly results in a serious problem whereby a dark current increases to give remarkable adverse effect on the clear image, the CMOS image sensor can be said to show particular effect thereof. However, this CMOS image sensor can provide the similar effect for reduction of crystal defect by introducing the epitaxial wafer as the element substrate for the other semiconductor device and forming at least a part of the interlayer insulation film deposited and formed on the active area with the plasma CVD-TEOS oxide film.

The present invention provides the following effects. As explained above, according to the present invention, a crystal defect in the substrate due to stress can be reduced, interfacial level generated by plasma damage can be recovered and a leak current can also be reduced. Therefore, a clear image can be obtained with the CMOS image sensor. Improvement can also be realized for the hot carrier in the fabrication of an ordinary semiconductor device other than the CMOS image sensor.

### BRIEF DESCRIPTION OF THE DRAWINGS

FIG. 1 is a graph for explaining comparison of life span of hot carriers depending on difference of interlayer structures.

FIG. 2 is a block diagram of the CMOS image sensor of the embodiment of the present invention.

FIG. 3 is a plan view illustrating a pixel of the CMOS image sensor.

FIG. 4 are cross-sectional views (No. 1) of the photodiode and reset transistor forming area illustrating a fabrication method of the CMOS image sensor of the embodiment of the present invention

FIG. 5 are cross-sectional views (No. 2) of the photodiode and reset transistor forming area illustrating the fabrication method of the CMOS image sensor of the embodiment of the present invention.

FIG. 6 are cross-sectional views (No. 3) of the photodiode and reset transistor forming area illustrating the fabrication method of the CMOS image sensor of the embodiment of the present invention.

FIG. 7 are cross-sectional views (No. 4) of the photodiode and reset transistor forming area illustrating the fabrication method of the CMOS image sensor of the embodiment of the present invention.

FIG. 8 are cross-sectional views (No. 5) of the photodiode and reset transistor forming area illustrating the fabrication method of the CMOS image sensor of the embodiment of the present invention.

FIG. 9 are cross-sectional views (No. 6) of the photodiode and reset transistor forming area illustrating the fabrication method of the CMOS image sensor of the embodiment of the present invention.

FIG. 10 are cross-sectional views (No. 7) of the photodiode and reset transistor forming area illustrating the fabrication method of the CMOS image sensor of the embodiment of the present invention.

FIG. 11 are cross-sectional views (No. 8) of the photodiode and reset transistor forming area illustrating the fabrication method of the CMOS image sensor of the embodiment of the present invention.

FIG. 12 are cross-sectional views (No. 1) of the peripheral CMOS circuit forming area illustrating the fabrication method of the CMOS image sensor of the embodiment of the present invention.

FIG. 13 are cross-sectional views (No. 2 of the peripheral CMOS circuit forming area illustrating the fabrication method of the CMOS image sensor of the embodiment of the present invention.

FIG. 14 are cross-sectional views (No. 3) of the peripheral CMOS circuit forming area illustrating the fabrication method of the CMOS image sensor of the embodiment of the present invention.

FIG. 15 are cross-sectional views (No. 4) of the peripheral CMOS circuit forming area illustrating the fabrication method of the CMOS image sensor of the embodiment of the present invention.

FIG. 16 are cross-sectional views (No. 5) of the peripheral CMOS circuit forming area illustrating the fabrication method of the CMOS image sensor of the embodiment of the present invention.

FIG. 17 are cross-sectional views (No. 6) of the peripheral CMOS circuit forming area illustrating the fabrication method of the CMOS image sensor of the embodiment of the present invention.

FIG. 18 are cross-sectional views (No. 7) of the peripheral CMOS circuit forming area illustrating the fabrication method of the CMOS image sensor of the embodiment of the present invention.

FIG. 19 are cross-sectional views (No. 8) of the peripheral CMOS circuit forming area illustrating the fabrication method of the CMOS image sensor of the embodiment of the present invention.

FIG. 20 is a timing chart illustrating operations of the CMOS image sensor of the embodiment of the present invention.

FIG. 21 is an equivalent circuit of a pixel of the CMOS image sensor.

### DESCRIPTION OF THE INVENTION

The preferred embodiments of the present invention will be explained with reference to the accompanying drawings.

### First Embodiment

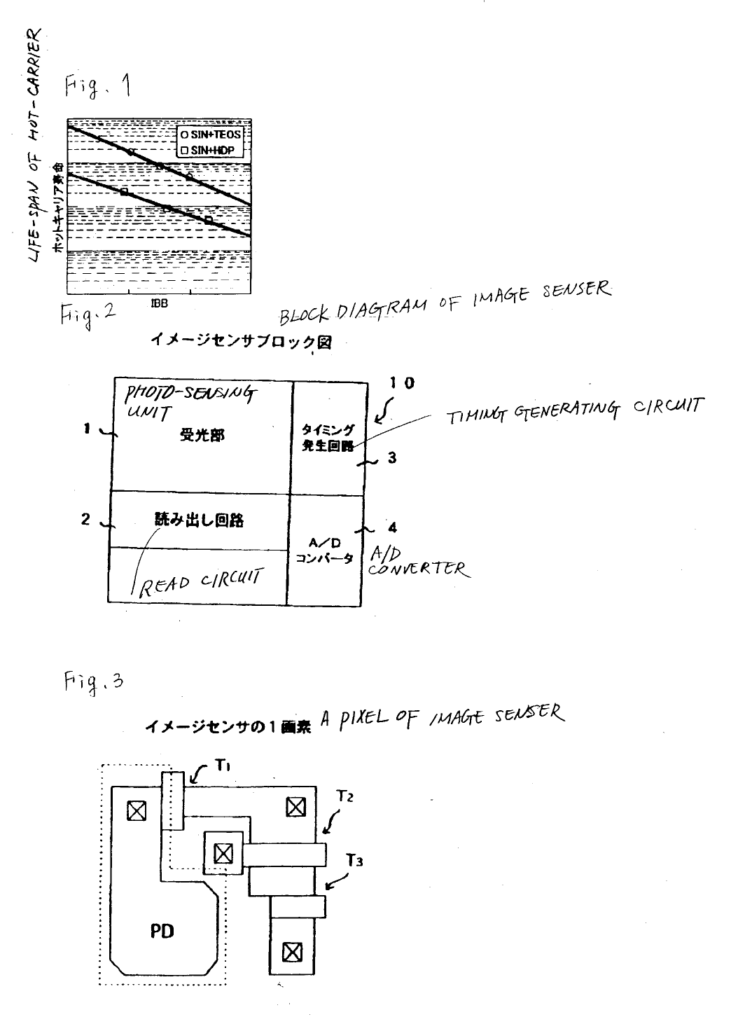

Referring to FIG. 2:

FIG. 2 is a block diagram of a CMOS image sensor of the first embodiment of the present invention. FIG. 3 is a plan view illustrating a pixel of the CMOS image sensor. As illustrated in FIG. 2, various circuits (such as, a photo-sensing unit 1, a read circuit 2, a timing generation circuit 3 and an A/D converter 4) are formed on a semiconductor substrate 10. Many pixels are arranged in the photo-sensing unit 1.

Referring to FIG. 3:

A pixel is formed, as illustrated in FIG. 3, of a photo-diode PD and three N-channel MOS transistors T1, T2, T3 and its equivalent circuit is illustrated in FIG. 21. Moreover, the circuits (such as, read circuit 2, timing generation circuit 3 and A/D converter 4) are formed of CMOS.

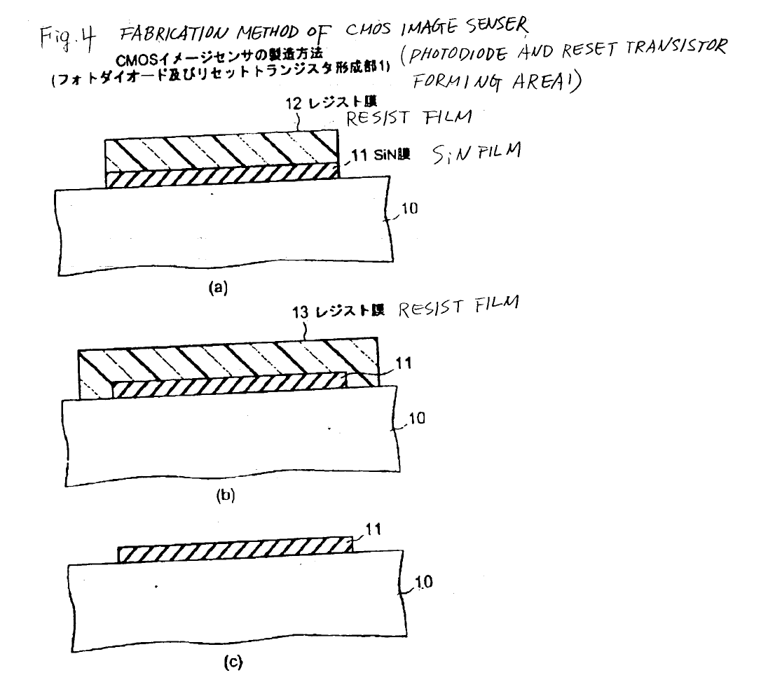

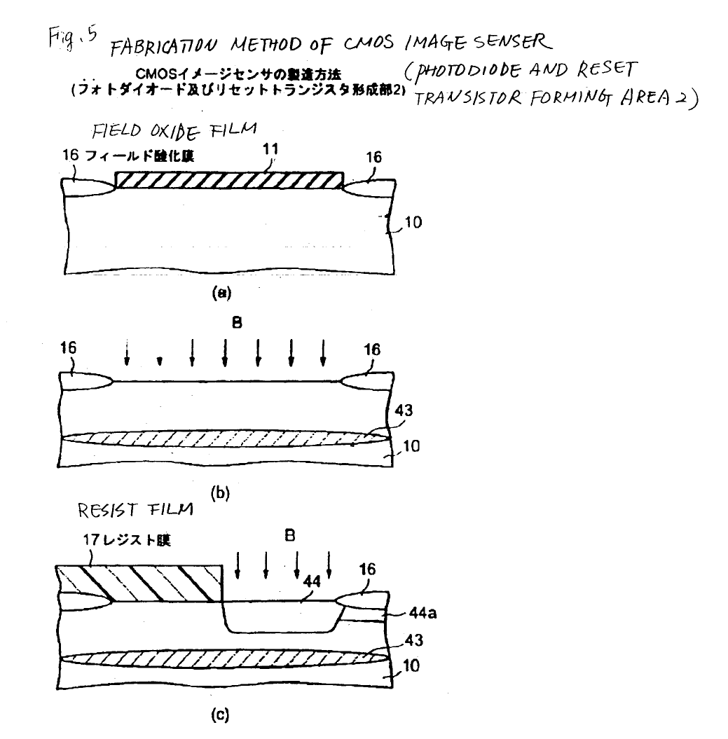

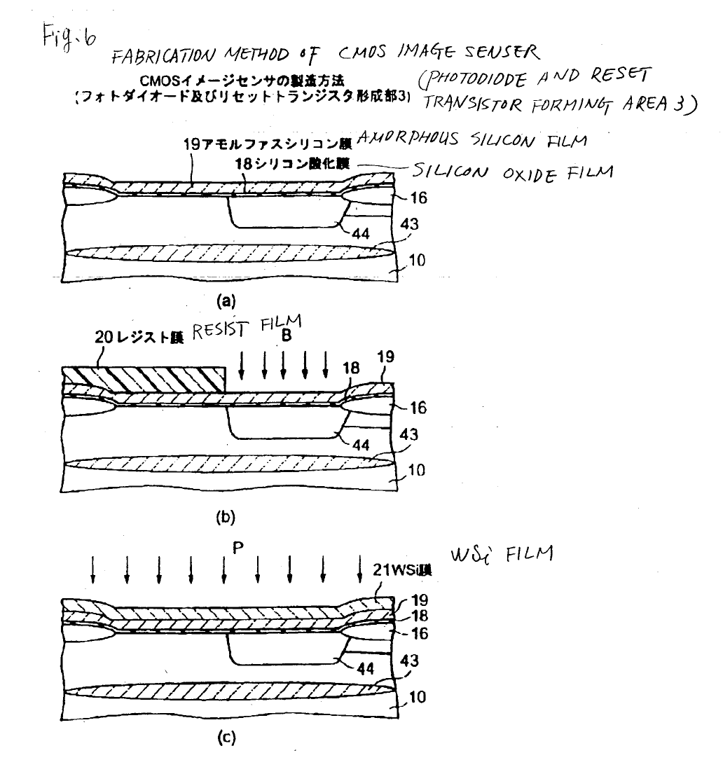

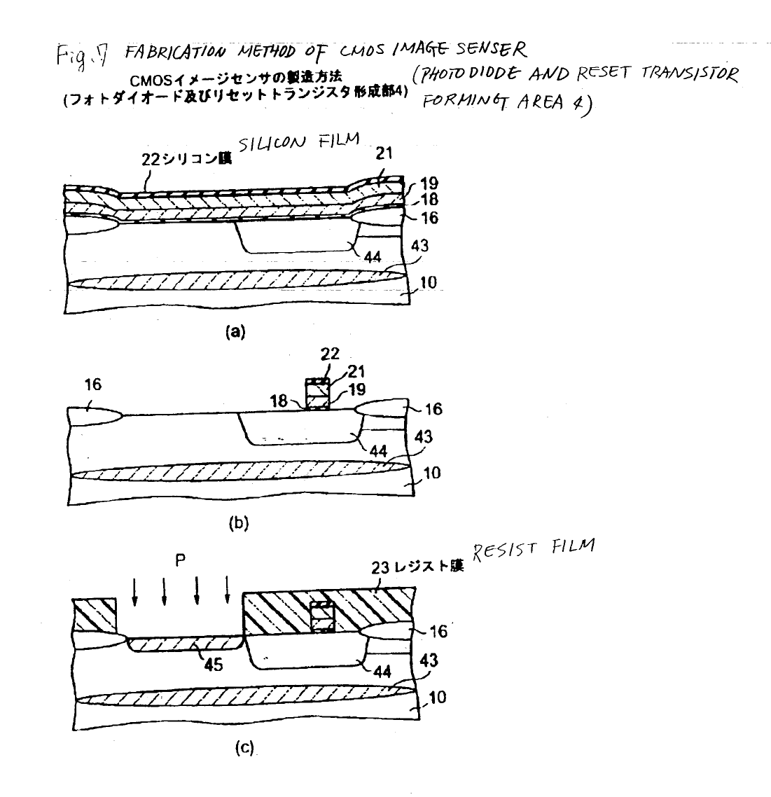

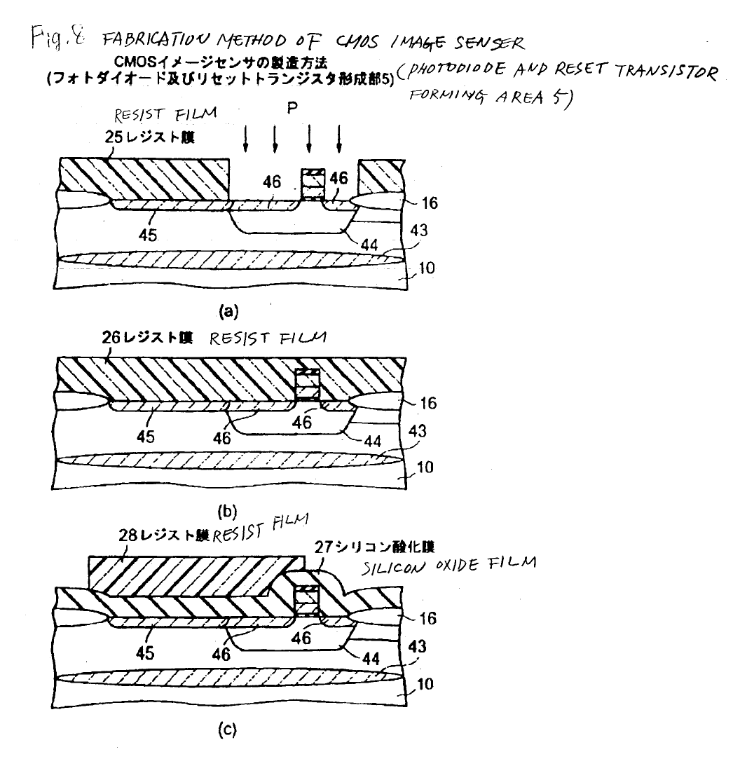

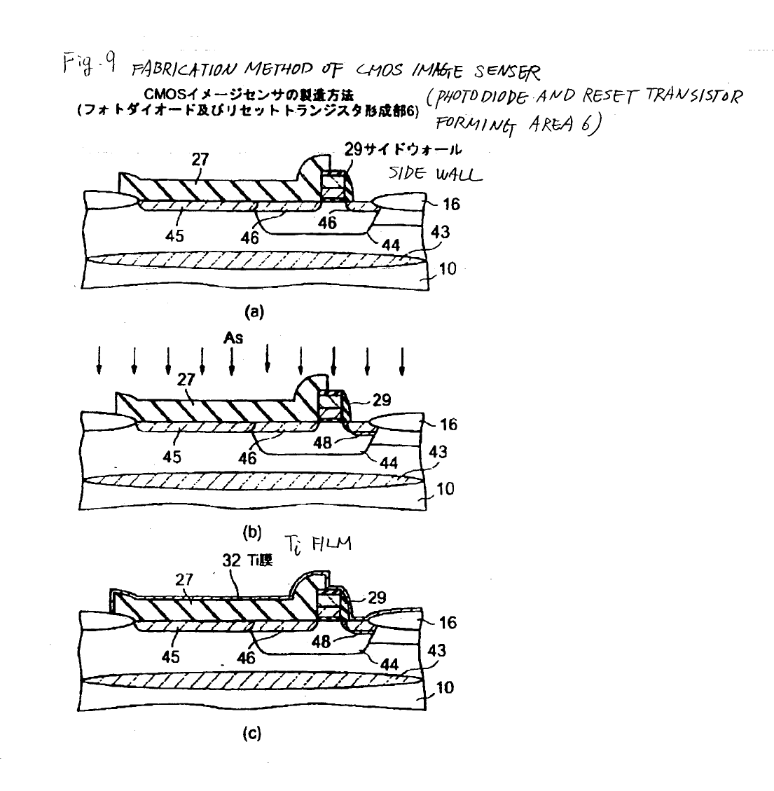

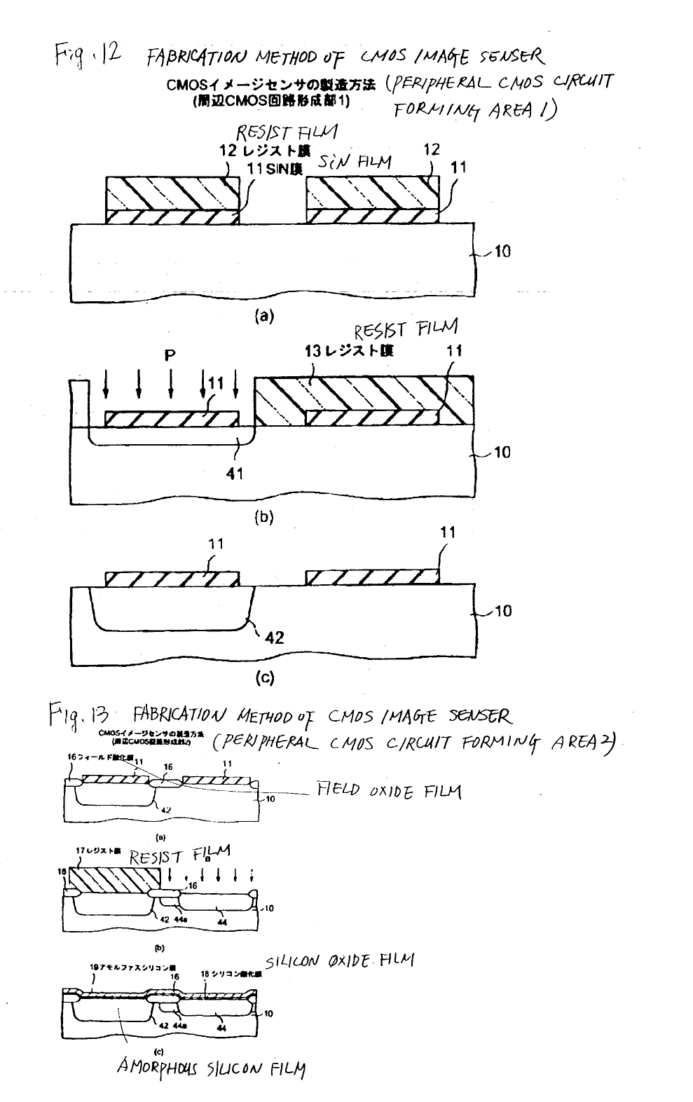

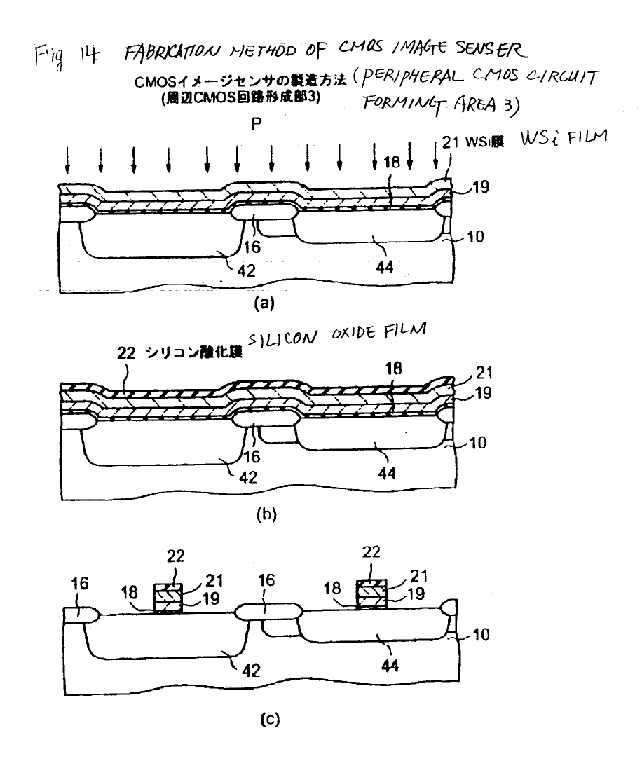

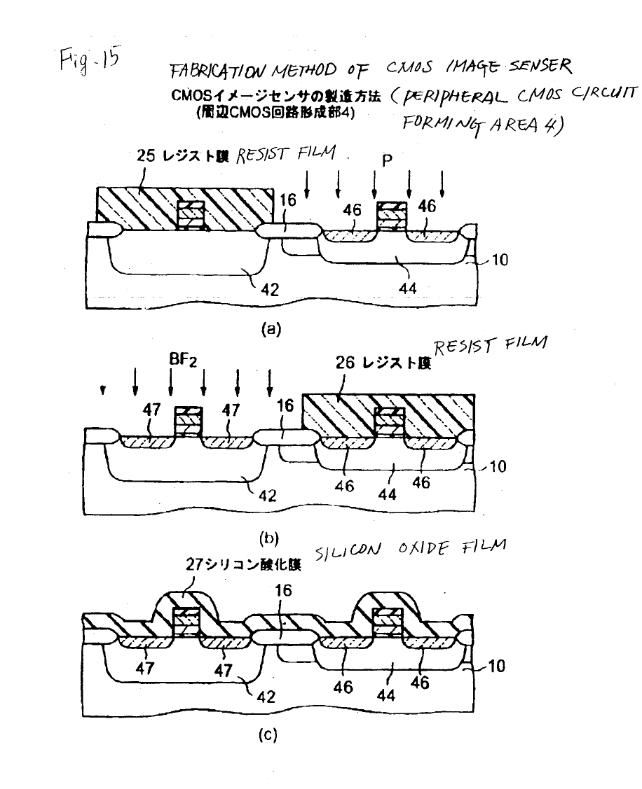

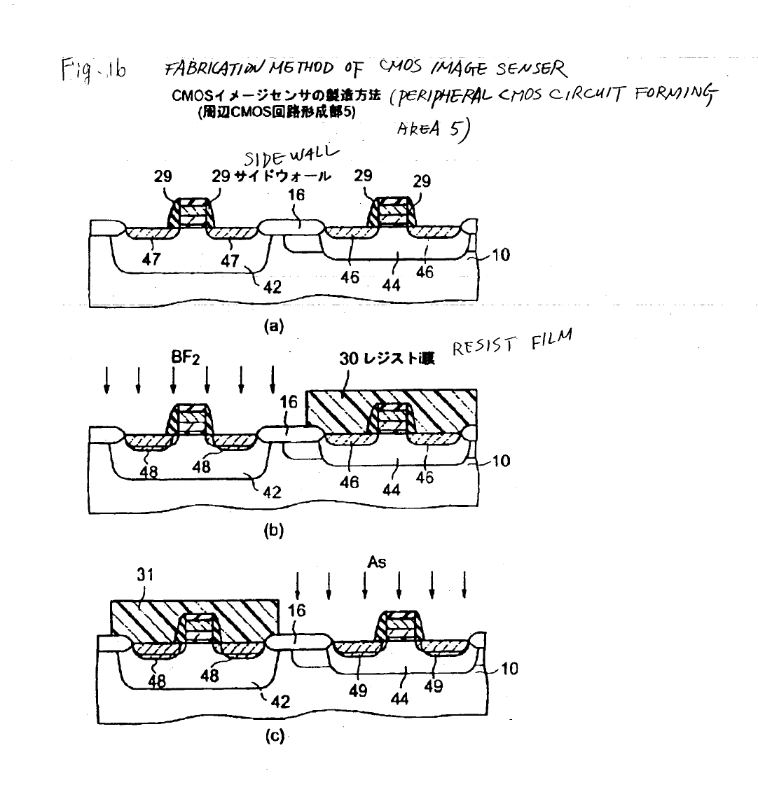

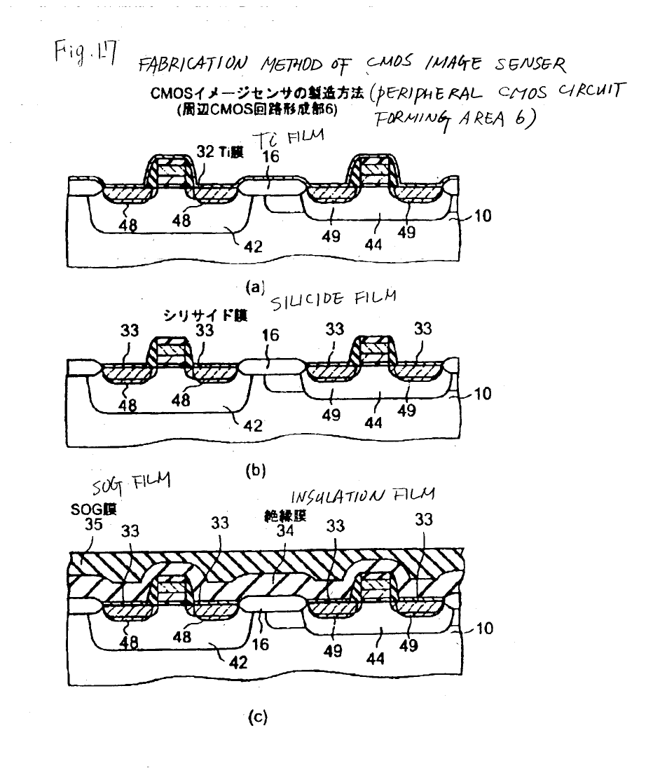

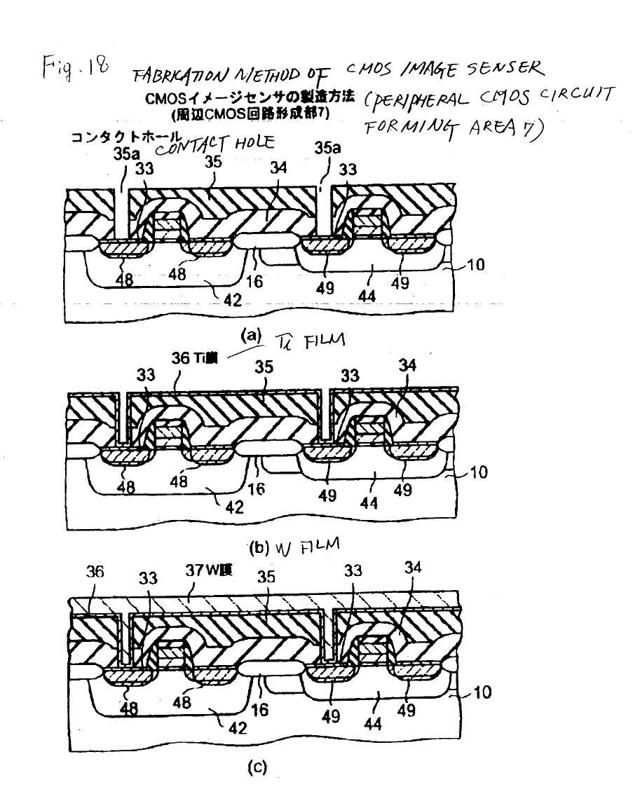

FIG. 4 to FIG. 19 illustrate a method of fabricating the CMOS image sensor of the first embodiment of the present invention. FIG. 4 to FIG. 11 are cross-sectional views of the photodiode and reset transistor, while FIG. 12 to FIG. 19 are cross-sectional views of the CMOS circuit part in the peripheral circuits.

Referring to FIG. 4 and FIG. 12:

As illustrated in FIG. 4(a) and FIG. 12(a), the surface of semiconductor substrate 10 is thermally oxidized and a silicon oxide film (not illustrated) is formed thereon in the thickness of about 3 nm. Thereafter, a silicon nitride film (SiN film) 11 is formed thereon in the thickness of about 115 nm. Here, as the semiconductor substrate 10, a silicon epitaxial wafer is selected. On this silicon nitride film 11, a resist film 12 having a window to the part corresponding to the field oxide film forming area is then formed and the silicon nitride film 11 is etched using this resist film 12 as the mask. Thereafter, the resist film 12 is removed.

Next, as illustrated in FIG. 4(b) and FIG. 12(b), the upper surface of the semiconductor substrate 10 is entirely coated with a photoresist film 13. A window is then opened to the part corresponding to the P-channel MOS transistor forming area through the exposing and developing processes. Phosphorus (P) is ion-injected to the semiconductor substrate 10 via this window under the condition of, for example, 180 keV, 1.4 Ω 10¹³/cm² to form an N-type impurity region 41.

Thereafter, as illustrated in FIG. 4(c) and FIG. 12(c), the resist film 13 is removed; and impurity is diffused through the heat treatment at the temperature of 1150 to form an N-well 42 to the P-channel MOS transistor forming area.

Referring to FIG. 5 and FIG. 13:

Next, as illustrated in FIG. 5(a) and FIG. 13(a), the heat treatment is conducted at the temperature of 900 to form a field oxide film 16 in the thickness of about 370 nm to the part not covered with the silicon nitride film 11. Thereafter, the silicon nitride film 11 is removed.

Next, a well is formed to the photodiode forming area. Namely, as illustrated in FIG. 5(b), boron (B) is ion-injected to the entire part of the photo-sensing unit under the condition of, for example, 600 keV and 3 Ω 10²/cm² to form a P-type impurity layer (well) 43 in the semiconductor substrate 10.

Thereafter, as illustrated in FIG. 5(c) and FIG. 13(b), the photodiode forming area and P-channel MOS transistor forming area are covered with a resist film 17; and boron (B) is then ion-injected to the N-channel MOS transistor forming area under the condition of, for example, 140 keV, 8 Ω 10¹²/cm² to form a P-well 44, while forming a channel stop layer 44a of the N-channel MOS transistor. Thereafter, the resist film 17 is removed.

Referring to FIG. 6 and FIG. 14:

Next, as illustrated in FIG. 6(a) and FIG. 13(c), the heat treatment is conducted at the temperature of 800 to form a silicon oxide film (gate oxide film) 18 to the surface of the semiconductor substrate 10 in the thickness of about 7 nm. Thereafter, an amorphous silicon film 19 is formed, with the CVD (Chemical Vapor Deposition) method, to the entire part of the upper surface of the semiconductor substrate 10 in the thickness of about 50 nm.

Thereafter, as illustrated in FIG. 6(b), after a resist film 20 is formed on the amorphous silicon film 19 of the photodiode forming area, boron (B) is ion-injected into the semiconductor substrate 10 not covered with the resist 20 under the condition of 30 keV, 8 Ω 10¹²/cm² in order to adjust the threshold values of the N-channel MOS transistor and P-channel MOS transistor. Thereafter, the resist film 20 is removed.

Referring to FIG. 6 and FIG. 14:

Next, as illustrated in FIG. 6(c) and FIG. 14(a), a WSi (tungsten silicon) film 21 is grown on the amorphous silicon film 19 in the thickness of 150 nm.

Thereafter, phosphorus (P) is ion-injected under the condition of, for example, 40 keV, 8 Ω 10¹⁵/cm² to reduce the resistance of the amorphous silicon film 19.

Refer to FIG. 7 and FIG. 14:

Next, as illustrated in FIG. 7(a) and FIG. 14(b), a silicon oxide film 22 is formed with the CVD method on the WSi film 21 in the thickness of about 45 nm; and an amorphous carbon film (not illustrated) is then formed with the PVD (Physical Vapor Deposition) method as a reflection preventing layer in the thickness of about 32 nm on the silicon oxide film 22.

Thereafter, as illustrated in FIG. 7(b) and FIG. 14(c), the amorphous carbon film, silicon oxide film 22, WS-i film 21, amorphous silicon film 20 and silicon oxide film 18 are etched with the photolithography to form a gate electrode of each MOS transistor.

Next, as illustrated in FIG. 7(c), a resist film 23 having a window to the photodiode forming area is formed and phosphorus (P) is ion-injected under the condition of, for example, 20 keV, 4 Ω 10¹⁵/cm² to the photodiode forming area to form an N-type impurity region 45. Thereafter, the resist film 23 is removed and the heat treatment is conducted for 10 seconds at the temperature of 1000.

Referring to FIG. 8 and FIG. 15:

Next, as illustrated in FIG. 8(a) and FIG. 15(a), a resist film 25 is formed covering the P-channel transistor forming area and photodiode forming area and phosphorus (P) is then ion-injected under the condition of, for example, 20 keV, 4 Ω 10¹³/cm² to both sides of the gate electrode of the N-channel MOS transistor forming area to form a low-concentration N-type impurity region 46. Thereafter, the resist film 25 is removed.

Next, as illustrated in FIG. 8(b) and FIG. 15(b), a resist film 26 is formed covering the N-channel MOS transistor forming area and photodiode forming area and BF₂ is ion-injected under the condition of, for example, 20 keV, 10¹³/cm² to both sides of the gate electrode of the P-channel MOS transistor forming area to form a low concentration P-type impurity region 47. Thereafter, the resist film 26 is removed.

Next, as illustrated in FIG. 8(c) and FIG. 15(c), a plasma CVD silicon oxide film 27 is formed at a thickness of 120 nm to the entire part on the upper surface of the semiconductor substrate 10. A photoresist film 28 is then formed on the plasma CVD silicon oxide film 27 and the part which will become a silicide block is patterned. In this embodiment, the part indicated with a broken line in FIG. 3, namely the area up to the part corresponding to the drain of reset transistor Ti from the photodiode forming area is covered with a resist film 28.

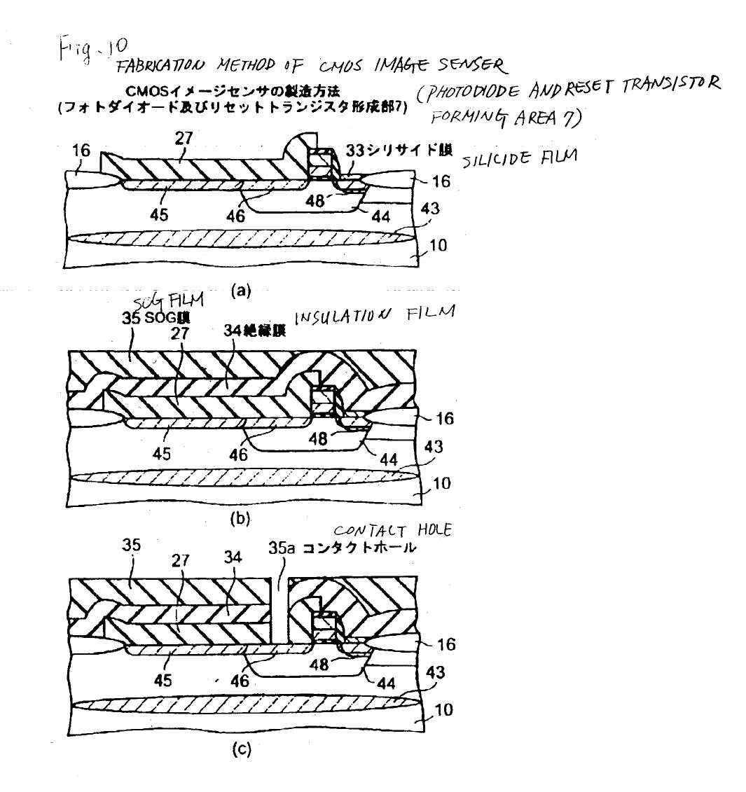

Referring to FIG. 9 and FIG. 16:

Next, as illustrated in FIG. 9(a) and FIG. 16(a), the plasma CVD silicon oxide film 27 is removed by the anisotropic etching method to form a side wall 29 to the side of the gate electrode. Thereafter, the resist film 28 is removed. Next, as illustrated in FIG. 16(b), a resist film 30 is formed covering the part other than the P-channel MOS transistor forming area; and BF₂ is then ion-injected to both sides of the gate electrode of the P-channel MOS transistor under the condition of, for example, 20 keV, 3 Ω 10¹⁵/cm² to form a high concentration P-type impurity region 48. Thereafter, the resist film 30 is removed.

Moreover, as illustrated in FIG. 9(b) and FIG. 16(c), a resist film 31 is formed covering the P-channel MOS transistor forming area and arsenic (As) is ion-injected to both sides of the gate electrode of the N-channel MOS transistor under the condition of, for example, 30 keV, 10¹⁵/cm² to form a high concentration P-type impurity region 49. Thereafter, the resist film 31 is removed.

The heat treatment is conducted for 10 seconds at the temperature of 1000 to activate the P-type impurity region 48 and N-type impurity region 49. Thereby, the N-channel MOS transistor and P-channel MOS transistor of the LDD structure can be completed.

However, the drain side of reset transistor T1 (the side connected to the photodiode) is not formed in the LDD structure, but the inventors of the present invention has confirmed by experiments that no problem occurs even when the LDD structure is introduced to the drain side.

Referring to FIG. 9 and FIG. 17:

Next, as illustrated in FIG. 9(c) and FIG. 17(a), Ti is sputtered to the entire part of the upper surface of the semiconductor substrate 10 to form a Ti film 32 in the thickness of 30 nm. Thereafter, the heat treatment is conducted for 90 seconds at the temperature of 700 to form the silicide of Ti film 32 at the part in contact with the semiconductor substrate 10.

Referring to FIG. 10 and FIG. 17:

Thereafter, as illustrated in FIG. 10(a) and FIG. 17(b), non-reacted Ti film 32 is removed by the etching method. Accordingly, a silicide film 33 is left on the surface of the source/drain regions of the MOS transistor. Thereafter, the heat treatment is conducted for 80 seconds at the temperature of 800 to stabilize the silicide film 33.

Next, as illustrated in FIG. 10(b) and FIG. 17(c), an insulation film 34 is formed to the entire part of the upper surface of the semiconductor substrate 10. This insulation film 34 is formed by, for example, depositing the plasma CVD silicon oxide film in the thickness of about 20 nm, and then depositing the plasma CVD nitride film (refractive index=2.24) at a thickness of about 70 nm. Thereafter, it is possible that the SOG (Spin On Glass) film 35 is coated on the insulation film 34 and then the surface is flattened, but it is more desirable to form the plasma CVD-TEOS oxide film 35. When the plasma CVD-TEOS oxide film is formed, it is required to make flat the surface with the well known method after deposition and formation of film.

Next, a photoresist film (not illustrated) is formed on the plasma CVD-TEOS oxide film 35 and a window is provided to the contact hole forming area through the exposing and developing processes.

Referring to FIG. 10 and FIG. 18:

As illustrated in FIG. 10(c) and FIG. 18(a), the impurity region 46 as the drain of the reset transistor and the contact hole 35a reaching the predetermined silicide film 33 are formed by etching, through this window, the plasma CVD-TEOS oxide film 35, and insulation film 34 (sequentially laminated film of the plasma CVD silicon oxide film and plasma CVD silicon nitride film). Thereafter, the resist film is removed.

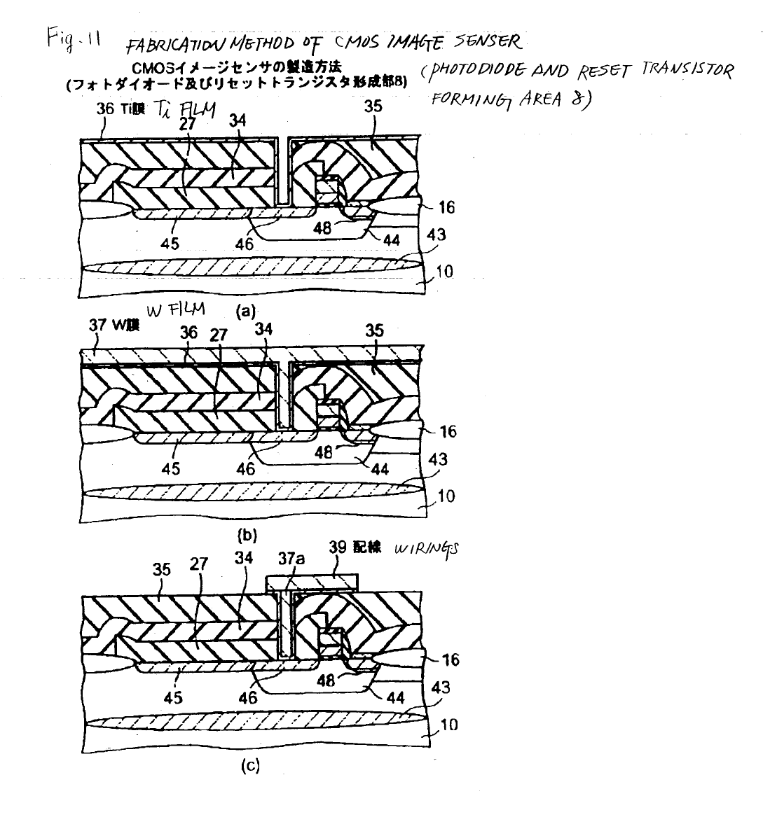

Referring to FIG. 11 and FIG. 18:

Next, as illustrated in FIG. 11(a) and FIG. 11(b), Ti is formed by the sputtering to the entire part in the thickness of 20 nm; and TiN is also formed by the sputtering in the thickness of 50 nm in order to form a Ti film 36. Thereafter, as illustrated in FIG. 11(b) and FIG. 18(c), a tungsten (W) film 37 is formed in the thickness of 800 nm to the entire part of the upper surface of the semiconductor substrate 10 and the contact hole 35a is filled with tungsten.

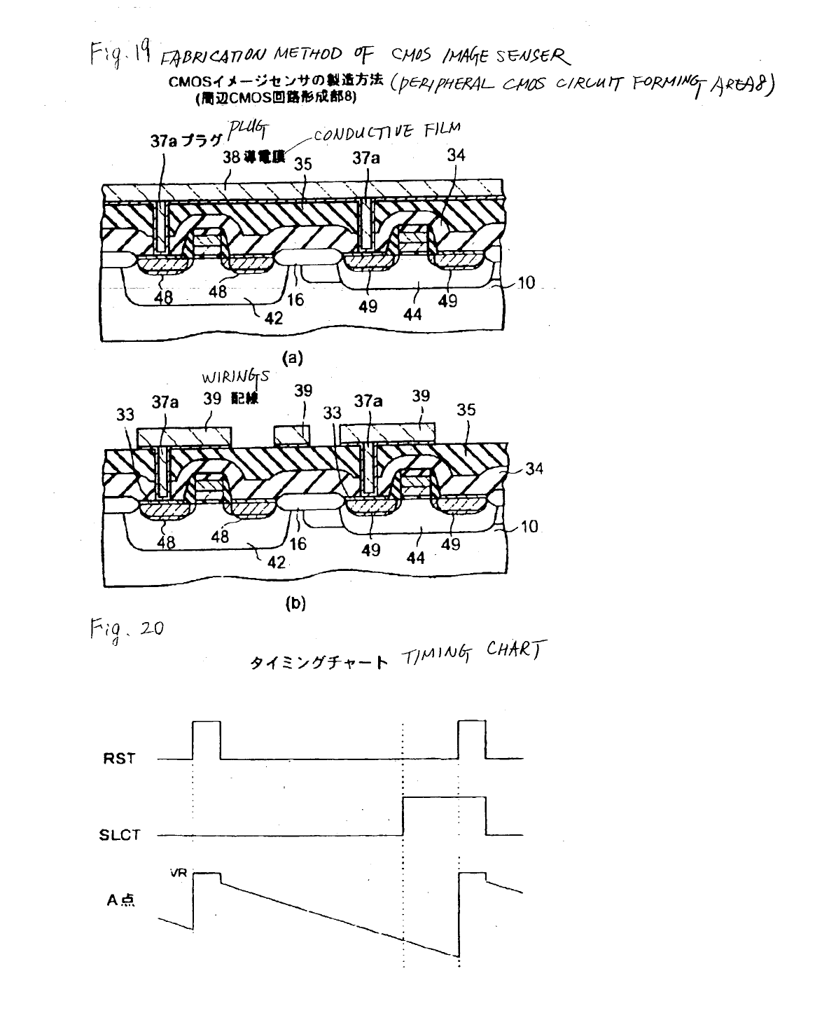

Referring to FIG. 11 and FIG. 19:

Thereafter, as illustrated in FIG. 19(a), the tungsten film 37 is polished with the CMP (chemical mechanical polishing) method to remove a part of the tungsten film 37 other than the contact hole 35a. Thus, the tungsten plug 37a can be formed. Ti is formed in the thickness of 20 nm and TiN at a thickness of 50 nm. Moreover, AlCu is formed thereon at a thickness of 500 nm, Ti at a thickness of 5 nm and TiN at a thickness of 100 nm in order to form a conductive film 38.

Next, as illustrated in FIG. 11(c) and FIG. 19(b), the conductive film 38 is patterned to form the predetermined wiring 39.

As explained above, the CMOS image sensor of this embodiment can be completed.

In the CMOS image sensor formed as explained above, a contact resistance of the connecting part is small at the part other than the drain of the reset transistor T1 because the source/drain of the transistor are connected to the wiring via the silicide film 33. Moreover, since the silicide film is not provided at the drain of the reset transistor which is directly connected to the photodiode PD, increase of leak current due to the atom of metal is prevented to improve the S/N ratio.

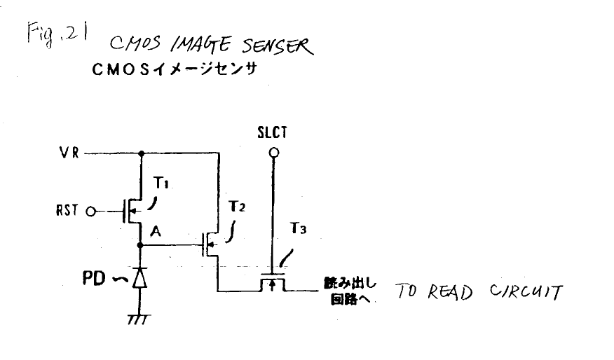

Referring to FIG. 20:

FIG. 20 is a timing chart for explaining the operation of the CMOS image sensor of this embodiment

The reset signal RST becomes high level in the constant period. When this reset signal RST becomes level, a potential in the cathode side of the photodiode PD (potential at the part corresponding to area A of FIG. 20) becomes a constant voltage (VR). Thereafter, when the light beam reaches the photodiode. PD after the reset signal RST becomes level, charges are generated in the photodiode PD depending on the light intensity.

With this charge, a potential of the point A (i.e., a gate voltage of the transistor T2) changes. When the select signal SLCT becomes level, an electrical signal depending on the potential of the point A is transferred to the read circuit (peripheral circuit) via the transistor T3. Accordingly, the signal is transferred to the peripheral circuit depending on the intensity of light having reached the photodiode PD.

The result of search for influence of a leak current of the CMOS image sensor actually fabricated by the fabrication method explained above will then be explained below.

As an embodiment, a CMOS image sensor has been fabricated with the method explained above. Comparison of leak currents can be realized by driving the CMOS image sensor in the dark place, setting a threshold value to an output code of the A/D converter and detecting the generation frequency of a signal which is higher in the level than the threshold value. More particularly, a generation frequency of the signal for which the output code of A/D converter becomes larger than 500 (corresponding to 500 mV) has been searched. As a result, the generation frequency has been the several tens of devices in the CMOS image sensor not introducing the epitaxial wafer (the sampling time of the A/D converter is 25 msec), but it has been 0 to several devices in the CMOS image sensor formed depending on the above embodiment as the comparison example. From these experimental results, it has been confirmed that the CMOS image sensor of the embodiment generates a leak current less than that of the CMOS image sensor of the comparison example.

The CMOS image sensor of the present invention is not limited to that in which the gate voltage of the reset transistor is changed for two stages of AH@ and AL@ levels, but can also be adapted to CMOS image sensor in which the gate voltage is changed in three or more stages. As explained above, the present invention is not limited only to the embodiment indicated, and a part of the conditions forming the embodiment can be modified as required.

In above embodiment, the desirable annealing temperature of Ti (titanium) is about 650; and when an aluminum (Al) or an aluminum alloy film obtained by mixing a very small amount of other metals to Al (aluminum) is employed as the wiring material, it is desirable to set the maximum temperature to a range of 400 to 450. Moreover, in regard to application flexibility of a laminated film of Ti (titanium)/TiN (titanium nitride), it is desirable to employ first Ti (titanium) in order to improve contact condition for the source/drain electrode so that the natural oxide film after opening the contact window can be effectively reduced. However, if Ti (titanium) is used, it is essential that TiN (titanium nitride) film is used overlapping on the Ti layer to improve stability and close contact condition of the upper metal wiring layer. As explained above, the laminated structure of Ti (titanium) and TiN (titanium nitride) is effective to effectively reduce the natural oxide film after opening of the contact window, maintain good contact condition, and to simultaneously realize stabilization and close contact condition of the upper metal wiring layer.

What is claimed is:

1. A CMOS image sensor comprising an epitaxial wafer as a substrate.

2. A CMOS image sensor comprising an element isolating insulation film which is provided with a LOCOS method on an element substrate for generating a bird's beak.

3. A CMOS image sensor described in claim 2, wherein the element isolating insulation film is a LOCOS film formed under a dry oxidation atmosphere.

4. A CMOS image sensor, comprising a plasma CVD nitride film which is employed as a part of an interlayer insulation film deposited and formed on an active region.

5. A CMOS image sensor, comprising a plasma CVD-TEOS oxide film which is employed as a part of an interlayer insulation film deposited and formed on an active region.

6. A CMOS image sensor, comprising an active region provided within an element substrate which is formed by heating and diffusing a conductive impurity within a furnace after ion injection.

7. A CMOS image sensor, comprising a contact window which is provided for mutual connection between an active region in an element substrate and wirings formed on the element substrate and a conductive impurity for enabling compensation for a contact is not injected to the bottom part of the contact window.

8. A CMOS image sensor, comprising a contact window which is provided for mutual connection between an active region in an element substrate and wirings on the element substrate and conductive impurity which enables compensation for a contact is formed to the bottom part of the contact window through thermal diffusion thereof after ion injection.

9. A CMOS image sensor, comprising wirings formed on an element substrate which does not include Ti (titanium).

10. A CMOS image sensor, comprising wirings consisting of Ti (titanium) formed on an element substrate, the layer consisting of W (tungsten) formed within a contact hole used for connection among the wirings and connection between an active region in the element substrate and the wirings and the TiN (titanium nitride) film formed covering upper and lower surfaces of the wirings.

11. A CMOS image sensor as in claim 10, wherein a part or an entire part of the TiN layer is formed by thermal nitride process of wirings consisting of Ti.

12. A method of fabricating a CMOS image sensor comprising the steps of:
depositing and forming a W (tungsten) wiring layer within a contact hole provided by opening a window to an interlayer insulation film on an element region within an element substrate and removing the W wiring layer from the external side of the contact window; and
conducting heat treatment to a structure of the remainder in the above process under an atmosphere including nitrogen and hydrogen or under a hydrogen atmosphere.

13. A semiconductor device, comprising an epitaxial wafer which is employed as an element substrate, and a plasma CVD-TEOS oxide film which is employed as a part of an interlayer insulation film deposited and formed on an ctive region.

14. A semiconductor device as in claim 13, wherein the element isolating insulation film provided on the element substrate is provided by a LOCOS method and bird's beak is also generated.

15. A semiconductor device as in claim 14, wherein the element isolating insulation film is a LOCOS film formed under a dry oxidation atmosphere.

16. A semiconductor device as in one of claims 13-15, wherein the active region provided in the element substrate is formed by heating and diffusing the conductive impurity in a furnace after an ion injection.

17. A semiconductor device as in one of claims 13-15, wherein the contact hole used for connection between the active region in the element substrate and wirings formed on the element substrate is provided and the conductive impurity which enables compensation for the contact is not injected to the bottom part of the contact window.

18. A semiconductor device as in one of claims 13-15, wherein the contact hole used for connection between the active region in the element substrate and wirings formed on the element substrate is provided and the conductive impurity which enables compensation for contact is formed through thermal diffusion after an ion injection of impurity to the bottom part of the contact window.

19. A semiconductor device as in one of claims 13-15, wherein the wirings formed on the element substrate do not include Ti (titanium).
